(19) United States
(12) Patent Application Publication
(10) Pub. No.: US 2008/0111174 A1
(43) Pub. Date: May 15, 2008

(54) MEMORY DEVICE AND A METHOD OF MANUFACTURING THE SAME

(75) Inventors: Peter Baars, Dresden (DE); Klaus Muemmler, Dresden (DE)

Correspondence Address: EDELL, SHAPIRO & FINNAN, LLC, 1901 RESEARCH BLVD., SUITE 400, ROCKVILLE, MD, 20850, US

(73) Assignee: QIMONDA AG, Munich (DE)

(21) Appl. No.: 11/559,563

(22) Filed: Nov. 14, 2006

(51) Int. Cl. H01L 27/108; H01L 21/8242

(52) U.S. Cl. 257/301; 438/243; 257/E21.646; 257/E27.084

(57) ABSTRACT

A memory device comprises an array of memory cells, the memory cells being at least partially formed in a semiconductor substrate having a surface, each of the memory cells including an access transistor and a storage capacitor for storing data, the storage capacitor including a first and a second capacitor electrodes and a capacitor dielectric disposed between the first and second capacitor electrodes. The first capacitor electrode extends to a first electrode height. The memory device also includes a peripheral portion including peripheral circuitry and a wiring layer. The wiring layer includes first lines, wherein a bottom surface of each of the first lines is disposed at a bottom surface height which is greater than 0.25 times the first electrode height, and each of the first lines has a line thickness less than 200 nm.

### BACKGROUND

Memory cells of a dynamic random access memory (DRAM) generally comprise a storage capacitor for storing an electrical charge which represents information to be stored (i.e., data), and an access transistor, which is connected with the storage capacitor. The access transistor comprises a first and a second source/drain region, a channel connecting the first and the second source/drain regions and a gate electrode controlling an electrical current flowing between the first and the second source/drain regions. The transistor is usually at least partially formed in a semiconductor substrate. The gate electrode forms part of a word line, and it is electrically insulated from the channel by a gate dielectric. By addressing the access transistor via the corresponding wordline, the data stored in the storage capacitor is read out to a corresponding bitline.

In known DRAM memory cells, the storage capacitor can be implemented as a trench capacitor in which the two capacitor electrodes are disposed in a trench that extends in the substrate in a direction perpendicular to the substrate surface.

According to another known implementation of the DRAM memory cell, the electrical charge is stored in a stacked capacitor, which is formed above the surface of the substrate. Usually, a memory device comprises an array of memory cells as has been described above and a peripheral portion or support portion. The peripheral portion refers to a portion at the edge of the memory cell array in which support circuits such as decoders, sense amplifiers and wordline drivers for activating a wordline are located. Generally, the peripheral portion of a memory device includes circuitry for addressing memory cells and for sensing and processing the signals received from the individual memory cells.

Typically, the peripheral portion is formed in the same semiconductor substrate as the individual memory cells. Hence, a manufacturing process by which the components of the memory cell array and the peripheral portion can be formed simultaneously is desirable.

If the storage capacitor of the memory cell is implemented as a stacked capacitor extending above the semiconductor substrate surface, the whole substrate surface may be covered by a thick insulating layer, for example, a silicon oxide layer. As a consequence, the contacts to the wiring layer in the peripheral portion must be defined so as to extend across the thick insulating layer. Therefore, the contacts require a high aspect ratio.

### SUMMARY

A memory device comprises an array of memory cells, the memory cells being at least partially formed in a semiconductor substrate having a surface, each of the memory cells including an access transistor and a storage capacitor for storing data, the storage capacitor including a first and a second capacitor electrodes and a capacitor dielectric disposed between the first and second capacitor electrodes. The first capacitor electrode extends to a first electrode height. The memory device also includes a peripheral portion including peripheral circuitry and a wiring layer. The wiring layer includes first lines, wherein a bottom surface of each of the first lines is disposed at a bottom surface height which is higher than 0.25 times the first electrode height, and each of the first lines has a line thickness less than 200 nm.

The above and still further features and advantages of the device and method will become apparent upon consideration of the following definitions, descriptions and descriptive figures of specific embodiments thereof, wherein like reference numerals in the various figures are utilized to designate like components. While these descriptions go into specific details of the device and method, it should be understood that variations may and do exist and would be apparent to those skilled in the art based on the descriptions herein.

The accompanying drawings are included to provide a further understanding of the memory device and the method of manufacturing the same are incorporated in and constitute a part of this specification. The drawings illustrate the embodiments of the described memory device and together with the description serve to explain the principles of the described memory device. Other embodiments and many of the intended advantages of the described memory device will be readily appreciated as they become better understood by reference to the following detailed description. The elements of the drawings are not necessarily to scale relative to each other. Like reference numerals designate corresponding similar parts.

### BRIEF DESCRIPTION OF THE DRAWINGS

The memory device and the method for manufacturing the same are explained in more detail below with reference to exemplary embodiments, where:

FIG. 1 shows a cross-sectional view of a semiconductor substrate when starting the described method;

FIG. 2 shows a cross-sectional view of a semiconductor substrate after defining an isolation opening;

FIG. 3 shows a cross-sectional view of a semiconductor substrate after performing a further processing step;

FIG. 4 shows a cross-sectional view of a semiconductor substrate after forming a thick silicon oxide layer;

FIG. 5 shows a cross-sectional view of a semiconductor substrate after defining peripheral contacts;

FIG. 6 shows a cross-sectional view of a semiconductor substrate after defining a wiring layer;

FIG. 7 shows a cross-sectional view of a semiconductor substrate after forming a further silicon oxide layer;

FIG. 8 shows a cross-sectional view of a semiconductor substrate after completing the storage capacitors;

FIG. 9 shows a cross-sectional view of a semiconductor substrate after defining openings;

FIG. 10 shows a cross-sectional view of a semiconductor substrate after filling the openings with a conductive material;

FIG. 11A shows a cross-sectional view of the completed memory device according to a first embodiment;

FIG. 11B shows a cross-sectional view of the completed memory device according to a second embodiment;

FIG. 12 shows a cross-sectional view of the completed memory device according to a third embodiment;

FIG. 13 shows an exemplary schematic plan view of a memory device according to an embodiment; and

FIG. 14 shows a flow-chart for illustrating an embodiment of the method of manufacturing the described memory device.

### DETAILED DESCRIPTION

As will be described hereinafter, a memory device comprises an array of memory cells, the memory cells being at least partially formed in a semiconductor substrate having a surface, each of the memory cells including an access transistor, the access transistor being at least partially formed in the semiconductor substrate; and a storage capacitor for storing data, the storage capacitor being operable to be accessed via the access transistor, the storage capacitor comprising at least a first and a second capacitor electrodes and at least a capacitor dielectric disposed between the first and second capacitor electrodes, wherein each of the first and second capacitor electrodes is disposed above the substrate surface, wherein the first capacitor electrode extends to a first height h, the first height h being measured from a bottom portion of the first capacitor electrode to a top portion of the first capacitor electrode, the memory device further comprising a peripheral portion including peripheral circuitry for controlling a read and a write operation of the memory cell array, the peripheral circuitry being connected to the memory cell array via lines; and a wiring layer provided in the peripheral portion, the wiring layer including first lines, wherein a bottom surface of each of the first lines is disposed at a second height h1 which is larger than 0.25× the first height h, the second height h1 being measured from the bottom portion of the first capacitor electrodes to a bottom surface of the first lines, and wherein each of the first lines has a thickness d, the thickness d being measured in a direction perpendicularly with respect to the substrate surface, wherein the thickness d<200 nm.

Moreover, a memory device, comprises an array of memory cells, the memory cells being at least partially formed in a semiconductor substrate having a surface, each of the memory cells including an access transistor, the access transistor being at least partially formed in the semiconductor substrate, and a storage component for storing data, the storage component being operable to be accessed via the access transistor, the storage component extending to a first height h, the first height h being measured from a bottom portion to a top portion of the storage component, the memory device further comprising a peripheral portion including peripheral circuitry for controlling a read and a write operation of the memory cell array, the peripheral circuitry being connected with the memory cells array, and wiring layer provided in the peripheral portion, the wiring layer including first lines, wherein a bottom surface of each of the first lines is disposed at a second height h1 which is higher than 0.25× the first height h, the second height h1 being measured from the bottom portion of the storage component to a bottom surface of the first lines and wherein each of the first lines has a thickness d, the thickness d being measured in a direction perpendicularly with respect to the substrate surface, wherein the thickness d<200 nm.

As will further be described in the following, a method of forming a memory device comprises providing a workpiece, the workpiece comprising a semiconductor substrate, a peripheral portion and a memory cell array portion being defined in the semiconductor substrate, the peripheral portion comprising peripheral circuitry being formed in the semiconductor substrate and the memory cell array portion comprising a plurality of transistors which are at least partially formed in the semiconductor substrate, providing a first insulating layer over a surface of the workpiece, thereafter, providing first contacts and a first wiring layer in the first insulating layer in the peripheral portion such that the first wiring layer is adjacent to a surface of the first insulating layer, thereafter, providing a second insulating layer over the surface of the first insulating layer, and thereafter providing storage capacitors in the array portion and providing second contacts in the peripheral portion, the second contacts being in contact with a first wiring layer.

In the following paragraphs, exemplary embodiments of the device and method are described in connection with the figures.

In the following detailed description reference is made to the accompanying drawings, which form a part hereof and in which is illustrated by way of illustrating specific embodiments in which the memory device and method may be practiced. In this regard, directional terminology such as “top”, “bottom”, “front”, “back”, “leading”, “trailing”, etc., is used with reference to the orientation of the Figures being described. Since components of embodiments of the described memory device can be positioned in a number of different orientations, the directional terminology is used for purposes of illustration and is in no way limiting. It is to be understood that other embodiments may be utilized and structural or logical changes may be made without departing from the scope of the described memory device and method. The following detailed description, therefore, is not to be taken in a limiting sense, and the scope of the described memory device and method for manufacturing the same are defined by the appended claims.

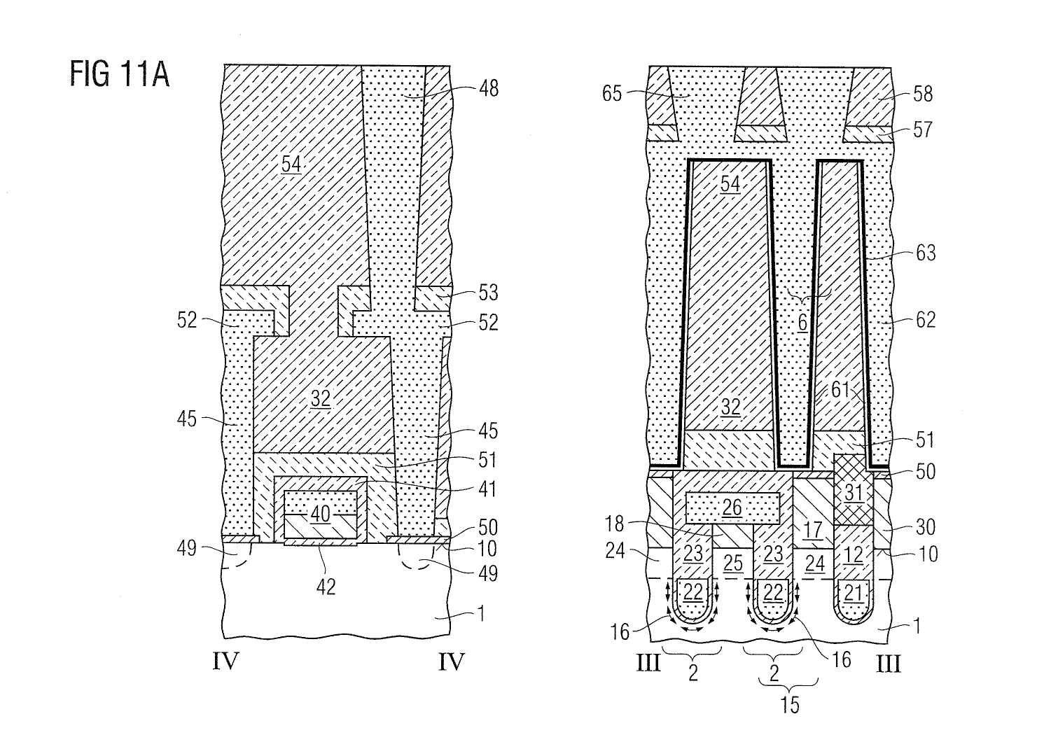

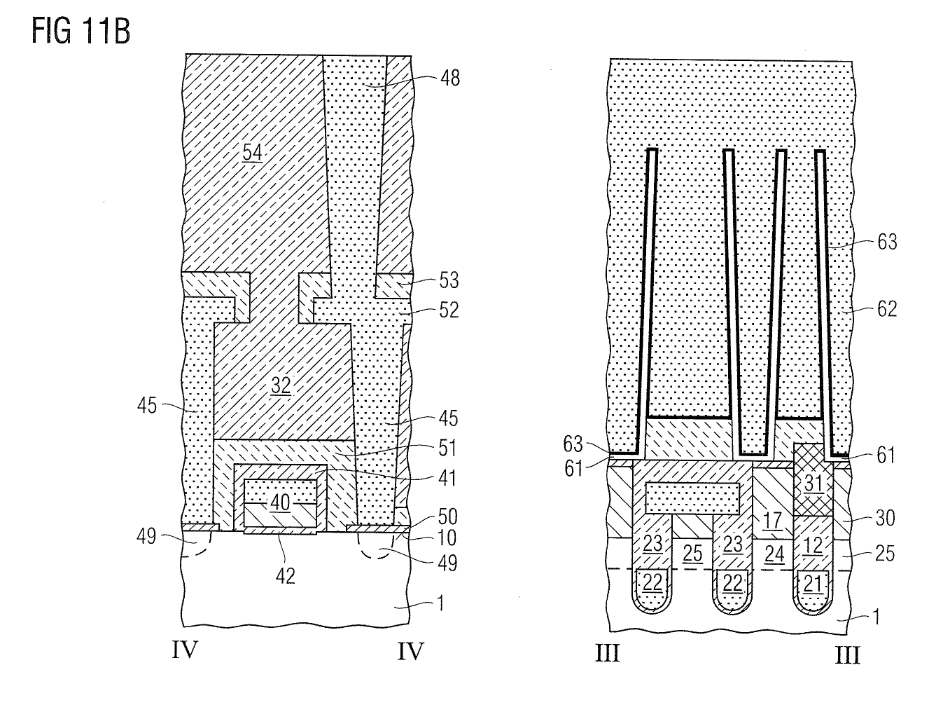

FIG. 11A shows a cross-sectional view of the completed memory device according to a first embodiment of the memory device. As can be seen, in the array portion between III and III, each memory cell 15 comprises a transistor 2 and a storage capacitor 6. Each of the storage capacitors 6 comprises a first capacitor electrode 61, a second capacitor electrode 62 and a capacitor dielectric 63 which is disposed between the first and the second capacitor electrodes 61, 62. The second capacitor electrode 62 is connected via the plate contact 65 to a predetermined potential. The first and the second capacitor electrodes can, for example, be made of a conductive material such as a metal, a noble metal or a metal alloy. Examples of the conductive material comprise polysilicon, TiN, TaN, TaSiN, Ru, WN and HfN. The materials of the first and second capacitor electrodes can be identical or different from each other. The capacitor dielectric can be made of any suitable dielectric material. Examples of the capacitor dielectric comprise a so-called high-k dielectric having a dielectric constant larger than 3.9. For example, HfO₂, HfSiO (hafniumsilicate), ZrO₂, Al₂O₃, HfAlO, TaO and any multilayer system comprising any of these layers may be taken.

The first capacitor electrode 61 is connected via a silicide layer 50, e.g., a cobalt silicide (CoSi) layer 50 and the capacitor contact 17 to the first source/drain portion 24. Due to the presence of the CoSi layer 50, a contact resistance between the capacitor contact 17 and the first capacitor electrode 61 is reduced. A transistor 2 is formed, comprising a first source/drain portion 24, a second source/drain portion 25 as well as a channel 16 which is disposed between the first and the second source/drain portions 24, 25. The conductivity of the channel 16 is controlled by the gate electrode 20 which forms part of a corresponding wordline 22. The upper surface of each of the wordlines 22 is disposed beneath the substrate surface 10. A wordline insulation layer 23 is disposed above each of the wordlines 22. The second source/drain portion 25 is connected via a bitline contact 18 with a bitline 26. The bitline 26 is disposed beneath each of the first and the second capacitor electrodes. To be more specific, the bitlines are embedded in a polysilicon layer 30.

Moreover, in the peripheral portion between IV and IV, peripheral transistors are formed. Each of the peripheral transistors comprises peripheral source/drain portions 49. The conductivity of the channel which is formed between peripheral source/drain portions 49 is controlled by the peripheral gate electrode 40 which is insulated from the channel by a peripheral gate dielectric 42. The peripheral source/drain regions 49 are connected with peripheral source/drain contacts 45. A silicide layer 50, e.g., CoSi, is disposed between the peripheral source/drain portions 49 and the peripheral source/drain contacts 45. Accordingly, the contact resistance is reduced. Each of the peripheral source/drain contacts 45 is connected with first lines 52. The lower surface of each of the first lines 52 of the peripheral transistors is disposed above the bottom surface of each of the first capacitor electrodes 61 of the storage capacitor 6 in the array portion. Moreover, the thickness of each of the first lines 52 is approximately less than 200 nm. Accordingly, the patterning of these first lines 52 is greatly simplified. Moreover, C1 contacts are provided, the C1 contacts 48 connecting the first lines 52 with wiring layers disposed above. In particular, the stacked thicknesses of the silicon oxide layers 32, 54 and 58 sum to approximately more than 2000 nm, for example, more than 2500 nm and even more than 3000 nm. Accordingly, in the array portion between III and III a capacitor having a large height and, hence, a large capacitance is obtained. Moreover, in the peripheral portion between IV and IV the manufacture of C1 contacts 48 is simplified due to the presence of the first lines 52 at a height of at least 0.25× the height of the storage capacitors.

FIG. 11B shows a second embodiment of the memory device. As is clearly to be understood, the structure of the wiring layer in the peripheral portion does not depend on the specific implementation of the storage capacitor. Accordingly, the described memory device can equally be applied to any other suitable implementation of the storage capacitor.

For example, the storage capacitors can as well be formed in such a manner, that protruding portions of the material constituting the first capacitor electrode 61 are formed so as to form hollow bodies. A capacitor dielectric 62 is deposited so as to cover the inner surface as well as the outer surface of each of these hollow bodies. Finally, a conductive material is provided so as to completely fill the structure, thus constituting the second capacitor electrode. Accordingly, in FIG. 11B all components are quite similar to the components shown in FIG. 11A, with the exception that the storage capacitors are formed in a different manner. Accordingly, as can be seen, the capacitor dielectric 62 and the second capacitor electrode 62 are disposed inside and outside the hollow bodies constituting the first capacitors electrodes 61.

As is known to one skilled in the art, the concept of forming C1 contacts in the peripheral portion may as well be implemented in memory cells which are based on a different cell concept.

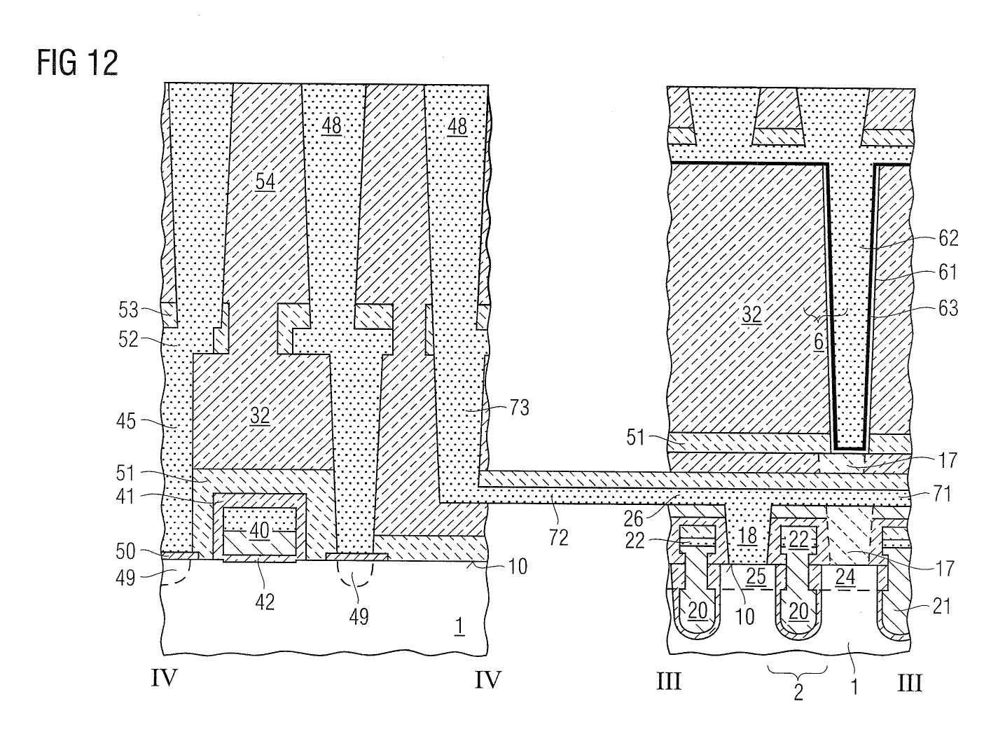

FIG. 12 shows a memory device according to a third embodiment of the memory device. According to this embodiment, the memory device is based on a different memory cell concept. As can be seen from FIG. 12 part of the wordlines 22 may extend above the substrate surface 10. Moreover, the bitlines 26 may extend so as to be perpendicular with respect to the wordlines 22. Accordingly, in the cross-sectional view shown in FIG. 12, the capacitor contacts 17, which connect the first source/drain portion 24 with the first capacitor electrode 61, are disposed before and behind the illustrated cross-sectional view as is indicated by hatchings. A transistor 2 is formed, comprising a first source/drain region 24, a second source/drain region 25 as well as a gate electrode 20. The gate electrode 20 may form part of the corresponding wordline 22 or may be electrically connected therewith. Data stored in the storage capacitor 6 may be read by activating the access transistor 2 via a corresponding wordline 22. The information is transmitted via the bitline contact 18 to the corresponding bitline 26. The bitline 26 forms part of the array M0 wiring layer 71. The array M0 wiring layer may be connected with a contact structure 73 in the peripheral portion via a bitline contact structure 72. The components of the peripheral portion illustrated in the left-hand part of FIG. 12 between IV and IV are similar to the components shown in FIG. 11, and a detailed description thereof is omitted, for the sake of convenience. In addition, contact structures 73 are provided for accessing the array M0 wiring layer 71 from the peripheral portion.

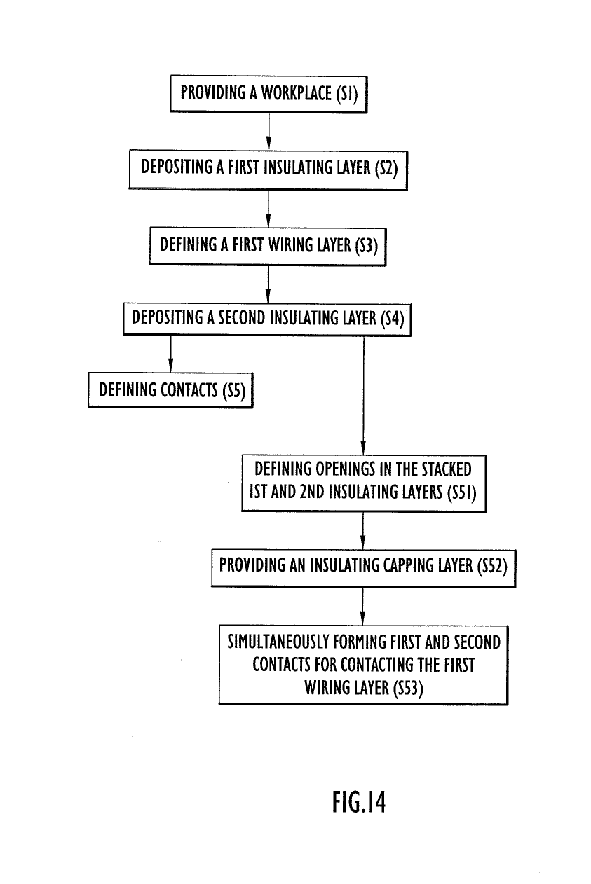

Moreover, FIG. 14 shows a flow-chart illustrating steps of an embodiment of the method of manufacturing a memory device. As is shown, first, a workpiece is provided (S1). In particular, the workpiece comprises a semiconductor substrate, in particular a silicon substrate including a peripheral portion and an array portion. Peripheral circuitry is formed in the peripheral portion and transistors are at least partially formed in the array portion. Moreover, several layers may be disposed on top of the semiconductor substrate.

Thereafter, a first insulating layer is deposited on top of the workpiece (S2). For example, the first insulating layer may comprise a silicon oxide layer having a thickness of more than 600 nm, e.g., more than 800 or even 900 nm. Thereafter, openings are formed in the first insulating layer in the peripheral portion. Moreover, a first wiring layer is defined (S3). In particular, the first wiring layer is adjacent to the surface of the first insulating layer. For example, the wiring layer may be disposed at least partially above or at least partially below the surface of the first insulating layer. Thereafter, a second insulating layer is deposited on the surface of the first insulating layer (S4). Then, the capacitors are formed in the stacked first and second layers in the array portion. Moreover, C1 contacts extending to the first wiring layer in the peripheral portion are defined (S5). For example, this may be accomplished by simultaneously etching the openings for defining the capacitors and the C1 contact openings in the second insulating layer.

Alternatively, this may as well be accomplished by defining openings in the stacked first and second insulating layer for defining the capacitors (S51). Thereafter, after completing the storage capacitors, an insulating capping layer is provided on top of the conductive material establishing the second capacitor electrode (S52). Then, plate contacts for contacting the capacitor electrodes as well as the second contacts for contacting the first wiring layer are formed simultaneously (S53). For example, this may be accomplished by etching the plate contacts in the capping layer and simultaneously etching the stacked second insulating layer and the capping layer for forming the second contacts (C1 contacts). For example, the second insulating layer may have a thickness of more than 1000 nm, e.g., more than 1500 nm and even more than 1800 nm.

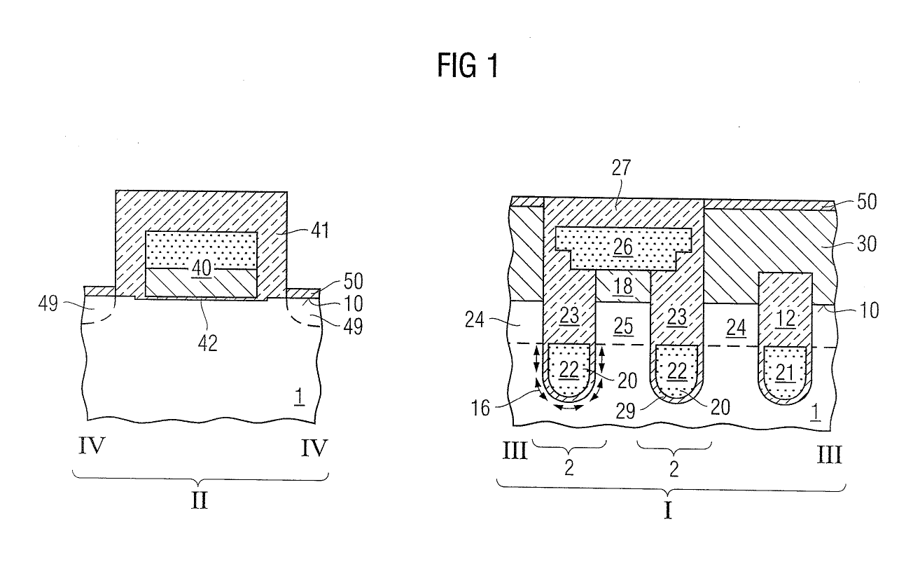

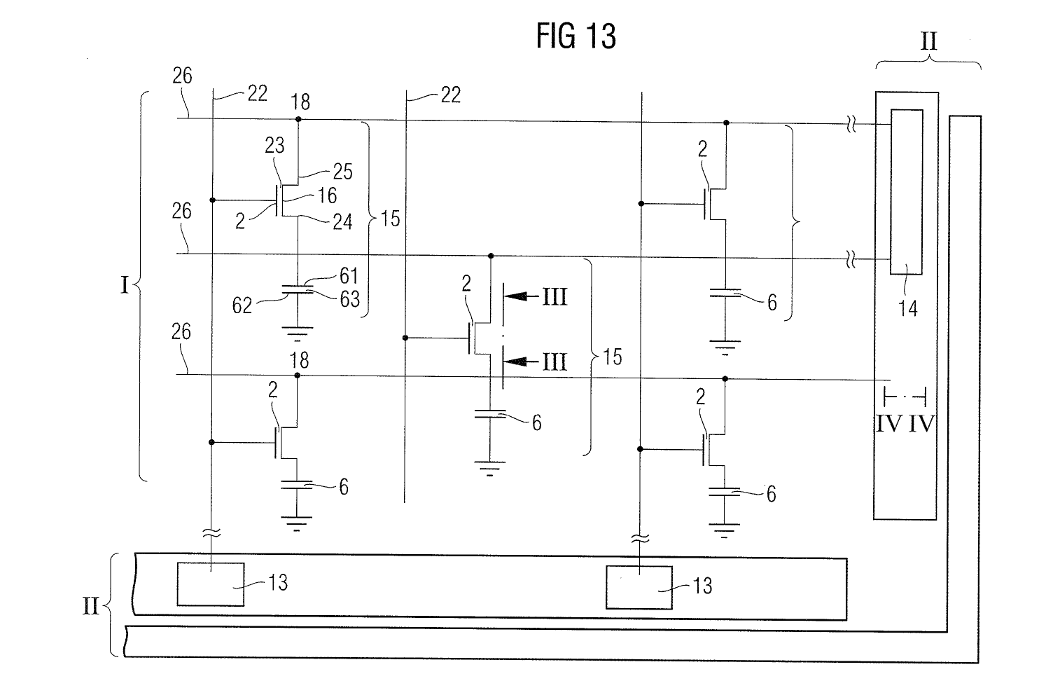

FIG. 1 shows an exemplary semiconductor substrate which may be used when starting the method of manufacturing the described memory device. In particular, in FIG. 1, the right-hand portion I denotes the array portion, in which the individual memory cells are formed. Moreover, the left-hand portion of FIG. 1 denotes the peripheral portion II in which circuits, as has been described above, are positioned. For example, the position of the cross-sections shown in FIG. 1 can be taken from FIG. 13. In particular, the cross-sectional view between III and III is taken from the active area of the memory cell array portion, whereas the cross-sectional between IV and IV is taken from the peripheral portion. As can be seen from FIG. 1, in a semiconductor substrate, in particular, a silicon substrate, a plurality of transistors 2 is formed. Each of the transistors comprises a first source/drain portion 24 as well as a second source/drain portion 25. A channel 16 is disposed between the first and the second source/drain portions. The conductivity of the channel 16 is controlled by a gate electrode 20 which is insulated from the channel 16 by a gate insulating layer 29. The second source/drain portion 25 is connected with a corresponding bitline 26 via a bitline contact 18. The first source/drain portion is to be connected with the storage electrode of a storage capacitor that is to be formed in the next steps. The substrate portion in which the transistor 2 is formed is denoted as the active area. Adjacent active areas may be insulated from each other by isolation trenches (not shown).

The specific implementation of the transistors 2 is arbitrary. In particular, the gate electrodes 20 which form part of a wordline can be implemented as buried wordlines, in which the entire conductive material is disposed beneath the substrate surface. In addition, in case the wordlines 22 are implemented as buried wordlines, an insulating material 23 is disposed above the wordlines 22 so as to extend up to the substrate surface. Moreover, optionally, neighboring transistors may be laterally insulated from each other by an isolation device 21 which acts like a transistor in an off-state thus avoiding a current flow between neighboring transistors. Nevertheless, any other isolation device may be used instead of the depicted ones. An insulating material 12 is disposed above the isolation device 21. The gate electrodes 20 as well as the isolation devices 21 form part of corresponding wordlines which run in a direction intersecting the direction of the active areas. A thick planarizing layer 30 which may be made of a conductive material, e.g. polysilicon, is disposed in the array portion so as to obtain a smooth surface. For example, the surface of the polysilicon layer 30 may be disposed above the upper surface of the bitline 26. An insulating material is disposed above the bitline 26. Moreover, the insulating material 12 above the isolation device 21 extends above the surface 10 of the semiconductor substrate 1.

In addition, in the peripheral portion, peripheral transistors are formed. For example, these peripheral transistors may comprise peripheral source/drain portions 49 which are disposed adjacent to the substrate surface 10 as well as a peripheral gate electrode 40. The gate electrode 40 is insulated from the channel by a peripheral gate insulating layer 42. Furthermore, an insulating material 41 is disposed so as to encapsulate the peripheral gate electrode 40. For example, a cobalt silicide layer 50 may be disposed in the array portion as well as in the peripheral portion. For example, the CoSi layer 50 may be formed by depositing a cobalt layer, followed by a silicidation step as is generally known to one skilled in the art.

As can further be seen from FIG. 1, the top most surface of the workpiece is disposed at a different height in the array portion and in the peripheral portion II. To be more specific, the surface of the workpiece is defined by the surface of the CoSi layer 50. As is obvious to one skilled in the art, the array portion may be as well implemented in a different manner. In particular, the transistors 2 may be implemented as planar devices or as transistors comprising gate electrodes which partially extend into the substrate surface.

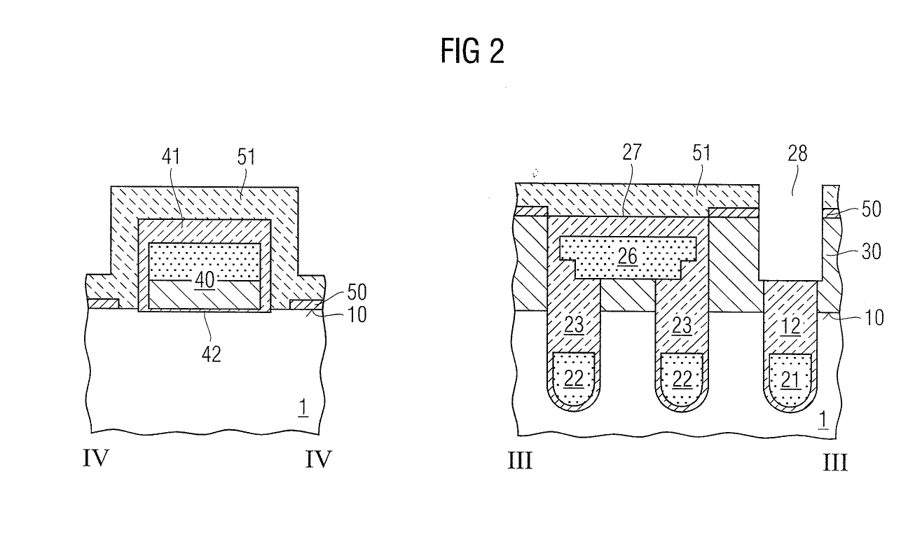

Starting from the structure shown in FIG. 1, first an etching step is performed so as to remove part of the vertical portions of the peripheral insulating layer 41. Optionally, by this step also part of the horizontal insulating material 27 may be recessed. Thereafter, a silicon nitride layer 51 is conformally deposited so as to form horizontal portions as well as vertical portions. Due to the recessing step, in the peripheral portion, part of the substrate surface 10 has been exposed. This part now is covered with the silicon nitride layer 51. Thereafter, isolation openings 28 are formed in the array portion. For example, this may be accomplished by performing a photolithographic step in which a suitable photoresist material is exposed using a mask with a suitable pattern. For example, the photoresist may be pattered using a mask including openings in the form of stripes or of dots. In particular, the stripes or dots are positioned above the insulating material 12. After a developing step, an etching step is performed, whereby the silicon nitride layer 51, the CoSi layer 50 as well as the polysilicon layer 30 are etched. As a consequence, openings 28 are formed. The openings 28 extend to the insulating material 12. The resulting structure is shown in FIG. 2.

As can be seen from FIG. 2, now, the peripheral portion between IV and IV is covered with a silicon nitride layer 51. Part of the silicon nitride layer 51 is in direct contact with the substrate surface 10. Moreover, the array portion between III and III is as well covered with the silicon nitride layer 51. In addition, openings 28 are formed so as to extend to the insulating material 12 covering the isolation device 21.

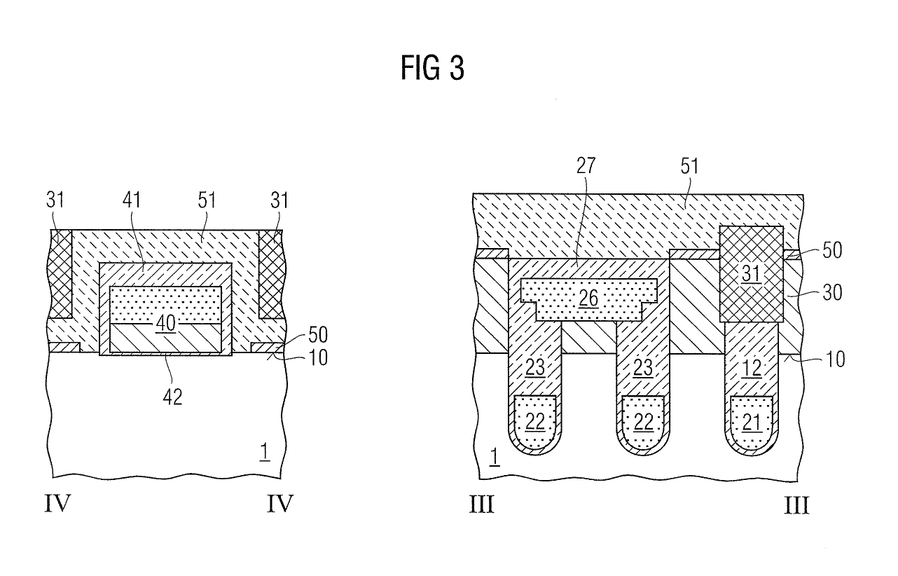

In the next step, a suitable insulating material such as a spin-on-glass 31 is deposited followed by an annealing step and a CMP (chemical mechanical polishing) step. Thereby, the openings 28 are filled with a spin-on-glass filling 31. Moreover in the peripheral portion, a planar surface is obtained. Thereafter, the silicon nitride layer is deposited. Then, a suitable photoresist material is applied, followed by a photolithographic step using a blockmask. As a consequence, the array portion between III and III is covered with a photoresist mask leaving the peripheral portion between IV and IV opened. Thereafter, an etching step is performed so as to etch silicon nitride material in the peripheral portion only. The resulting structure is shown in FIG. 3.

As can be seen from FIG. 3, now, the spin-on-glass filling 31 is covered by a silicon nitride layer 51 whereas the additional silicon nitride layer 51 is removed from the peripheral portion between IV and IV. Moreover, a planar surface is present in the peripheral portion.

Thereafter, a silicon oxide layer 32 is deposited. In particular, the thickness of this silicon oxide layer depends on the height at which the metallization layer in the peripheral portion is to be formed. For example, the silicon oxide layer 32 may have a thickness of more than 600 or more than 800 or 900 nm. By way of example, the thickness of the silicon oxide layer 32 may not exceed 1000 nm. Optionally, a planarization step may be performed. Then, in the peripheral portion between IV and IV, peripheral contact openings 43 are defined. For example, this may be accomplished by photolithographically patterning these openings. Thereafter, an etching step which is selective to silicon nitride is performed, thus stopping on the surface of the silicon nitride layer 51. In this respect, the term “selective etching step” refers to an etching process having a much higher etching rate for silicon oxide, for example, than for silicon nitride. For example, the ratio of the etching rates may be more than 4:1 or even more than 6:1, wherein 4 refers to the etching rate of silicon oxide and 1 refers to the etching rate of silicon nitride.

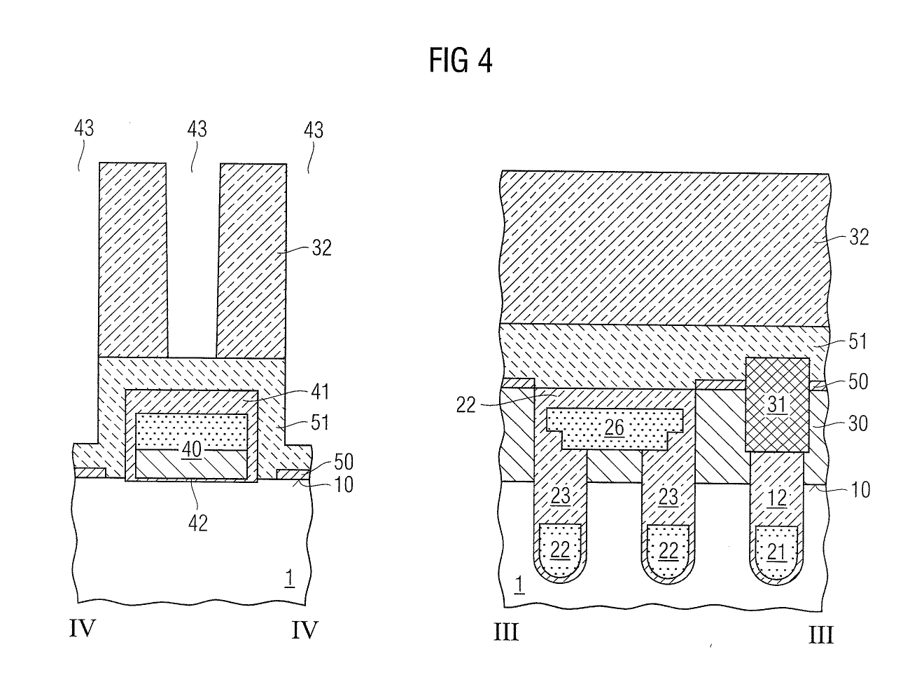

As is shown in FIG. 4, as a consequence, the array portion between III and III is covered with the silicon oxide layer 32. Moreover, in the peripheral portion between IV and IV, the silicon oxide layer 32 is present. In addition, openings 43 are formed in the silicon oxide layer 32. Thereafter, an etching step for etching silicon nitride material is performed, followed by a selective etching step for etching silicon oxide. As a consequence, the openings 43 are extended so as to be in contact with the conductive material of the peripheral gate electrode 40 or the surface of the CoSi layer 50, respectively. Nevertheless, as is obvious to one skilled in the art, any other sequence of suitable etching steps may be performed for extending the openings 43 to the corresponding contact portion. Then, a conductive filling is provided, followed by a CMP step. For example, the conductive filling may comprise a tungsten filling, optionally, with a suitable liner.

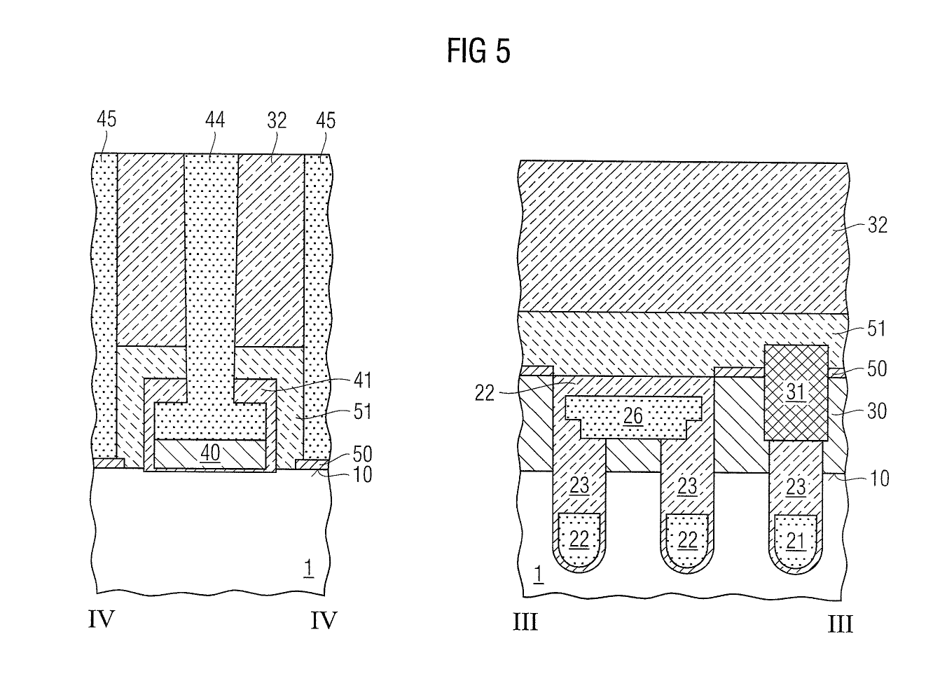

The resulting structure is shown in FIG. 5. As can be seen, the array portion between III and III remains unchanged, whereas in the peripheral portion between IV and IV, the conductive filling is provided. Accordingly, in the peripheral portion a peripheral gate contact 44 and peripheral source/drain contacts 45 are provided.

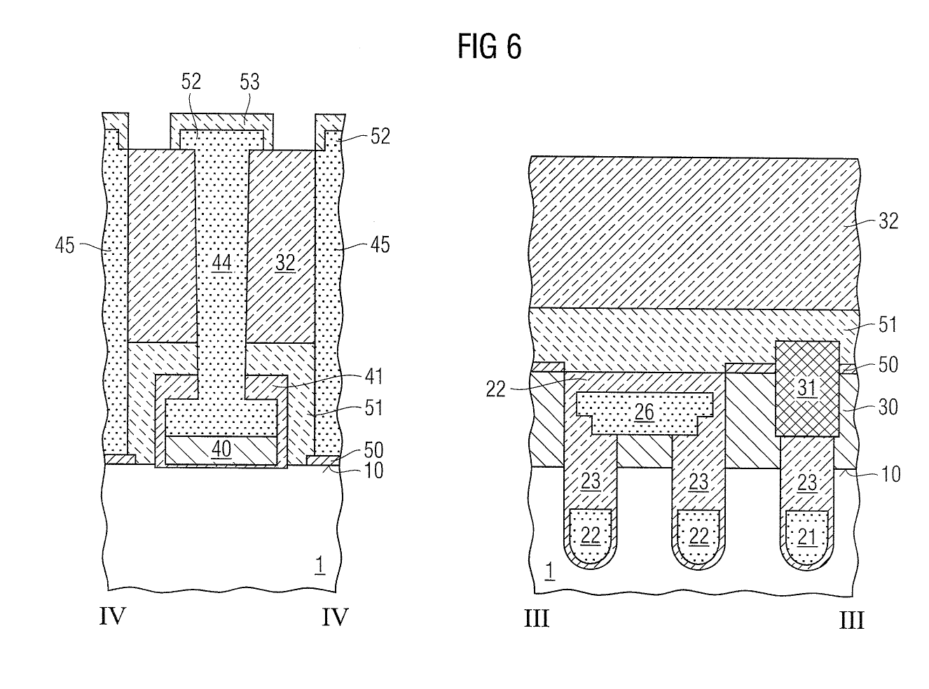

Thereafter, the M0 wiring layer is defined in the peripheral portion between IV and IV. To be more specific, the M0 wiring layer is a wiring layer which extends in a direction which intersects the depicted cross-section. Accordingly, each of the lines of the M0 wiring layer extends back and forth from the illustrated plane of the drawing. For example, the M0 wiring layer may be disposed on top of the silicon oxide layer 32. Accordingly, a conductive material is deposited. For example, a tungsten layer may be deposited followed by a silicon nitride layer 53. Then, a lithographic step is performed so as to define first lines 52 which extend from the illustrated cross-sectional view to the viewer or away from the viewer. For example, an etching step is performed so as to etch the conductive material using a carbon hardmask layer. As a consequence, first lines 52 are formed. Thereafter, a suitable material for forming a spacer may be deposited. For example, this may be accomplished by conformally depositing a silicon nitride layer and performing an anisotropic etching step which etches the horizontal portions of the silicon nitride layer. As a consequence, the structure shown in FIG. 6 is obtained.

As can be seen from FIG. 6, the array portion between III and III remains unchanged. Moreover, in the peripheral portion between IV and IV, first lines 52 are formed, each of the first lines 52 being covered with a silicon nitride layer 53. Each of the first lines 52 is connected with a peripheral circuitry via corresponding peripheral contacts, for example the peripheral gate contact 44 and the peripheral source/drain contact 45. Each of the first lines 52 extends in one or more different directions so as to intersect the illustrated cross-sectional view.

Thereafter, another insulating layer is deposited. For example, a silicon oxide layer 54 having a thickness of approximately more than 1000 nm for example, more than 1500 nm and, as a further example more than 1800 nm is deposited. For example, the thickness of this silicon oxide layer 54 may not exceed 2500 nm. This further silicon oxide layer 54 fills the space between adjacent first lines 52, for example. The silicon oxide layer may be deposited by performing, first, a HDP (high density plasma) method, followed by a PECVD (Plasma Enhanced Chemical Vapor Deposition) method using, for example, TEOS (tetra ethyl orthosilicate) as a starting material. As a consequence, in the array portion between III and III, the surface of the silicon nitride layer 51 is covered with a thick silicon oxide layer. Then, in the array portion between III and III the storage capacitors are defined. Accordingly, using a suitable photomask, openings are formed in the stacked silicon oxide layers 32, 54. For example, this may be accomplished by depositing a suitable hard mask layer (not shown) on top of the silicon oxide layer 54. The hard mask layer is patterned using a photomask, as is common. Using the patterned hard mask as an etching mask, an etching step is performed which etches silicon oxide material selectively with respect to silicon nitride. After performing this selective etching step, the opening formed in the silicon oxide layer extends to the upper surface of the silicon nitride layer 51. Thereafter, the hard mask layer may be removed, followed by an etching step which etches silicon nitride selectively with respect to silicon oxide and CoSi, for example. Then, a bottom electrode is deposited. For example, this may be accomplished by depositing a conductive material, such as TiN. Thereafter, the conductive layer is removed from the upper surface of the silicon oxide layer 54.

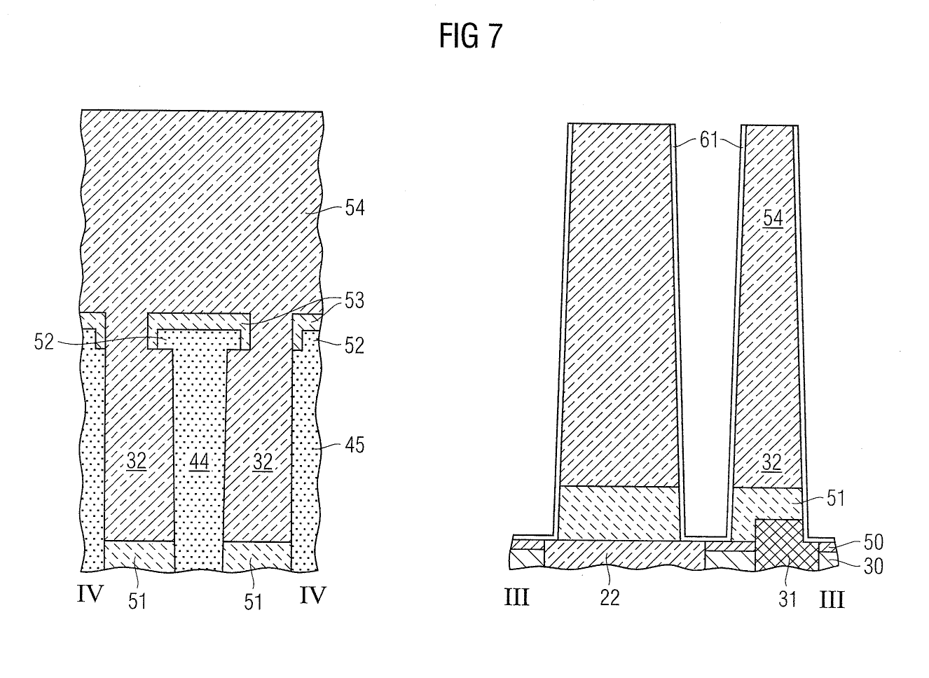

The resulting structure is shown in FIG. 7. As can be seen, in the peripheral portion between IV and IV, a further silicon oxide layer 54 is disposed on top of each of the first lines 52. Moreover, in the array portion between III and III, a bottom electrode 61 of each of the storage capacitors is formed. The bottom electrode 61 is in contact with the CoSi layer 50 and the polysilicon layer 30. Depending on the capacitor structure to be formed, now, the silicon oxide material 54 and 32 may be completely removed from the array portion, thus leaving protruding portions of the conductive material constituting the first capacitor electrodes. Although this modification is not explicitly shown in the drawings, it is clearly to be understood that this embodiment is included by the scope of the described memory device. The removal of the silicon oxide layers 32, 54 from the array portion can be accomplished by providing as suitable etch stop between the array portion and the peripheral portion so as to avoid the silicon oxide material being present in the peripheral portion from being attacked by the etching. Moreover, the peripheral portion should be protected by a corresponding blockmask. As a result, in the array portion only protruding portions of conductive material constituting the first capacitor electrode will remain on the surface of the workpiece. An exemplary cross-sectional view of the memory device resulting from this processing sequence is shown in FIG. 11B. Nevertheless, for the sake of convenience, in the following, the process for manufacturing the memory device comprising storage capacitors which are embedded in an insulating material will be further explained.

Thereafter, independent from the specific implementation of the storage capacitor in the array portion, the capacitors are completed by depositing a suitable dielectric material followed by a conductive material constituting the second capacitor electrode. For example, the dielectric material for constituting the capacitor dielectric may be selected from the materials mentioned above. Moreover, the second capacitor electrode may be formed of TiN, a combination of TiN and tungsten or any other material as mentioned above. For example, the conductive material for constituting the second capacitor electrode 62 may be deposited so that each of the capacitor openings is filled and, in addition, a layer 56 is formed. Thereafter, optionally, an insulating layer such as a silicon nitride layer 57 may be deposited on top of the tungsten layer 56. Thereafter, the array portion is covered with a blockmask, leaving the peripheral portion between IV and IV uncovered. An etching step is performed so as to remove the silicon nitride layer, the tungsten layer, the TiN layer as well as the dielectric layer 63 from the surface of the silicon oxide layer 54 in the peripheral portion between IV and IV.

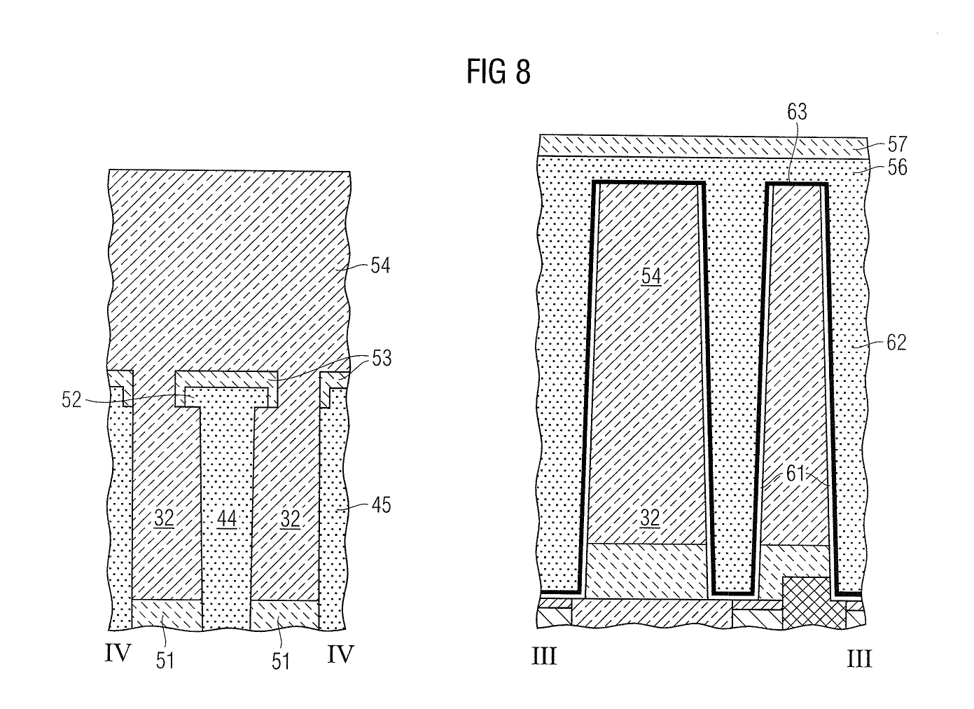

The resulting structure is shown in FIG. 8. As can be seen from FIG. 8, now, the peripheral portion between IV and IV remains unchanged. Moreover, in the array portion between III and III, the storage capacitors are completed. Each of the storage capacitors comprises a first capacitor electrode 61, a second capacitor electrode 62 as well as a capacitor dielectric 63 which is disposed between the first and the second capacitor electrodes.

Thereafter, another silicon oxide layer 58 is deposited, followed by a CMP step for obtaining a planar surface. Then, in the array portion between III and III plate contact openings 64 are defined, while in the peripheral portion between IV and IV, C1 contact openings 46 are formed. For example, this may be accomplished by performing a photolithographic step using a suitable mask. Accordingly, the plate contact openings 64 in the array portion as well as the C1 contact openings 46 in the peripheral portion may be formed by a simultaneous patterning step which simultaneously patterns the photoresist layer in the array portion as well as in the peripheral portion. For example, the etching step for etching these openings may be a selective etching step which etches silicon oxide selectively with respect to silicon nitride. As a consequence, the plate contact openings 64 in the array portion as well as the C1 contact openings 46 in the peripheral portion may be formed by a common etching step which etches different depths of the insulating material. Thereafter, an etching step is performed so as to etch the silicon nitride layers 57 and 53, respectively. As a consequence, in the array portion between III and III the plate contact openings 64 extend to the surface of the tungsten layer. Moreover, in the peripheral portion between IV and IV, the C1 contact openings 46 extend to the surface of the first lines 52. Due to the fact that the bottom surface of the first lines 52 are present at a height of more than 0.25× (the height of the capacitors), a step of etching the silicon oxide layer 54 so as to define C1 contact openings 46 is very relaxed. To be more specific, the lines 52 may serve as landing pads for forming the C1 contact openings 46.

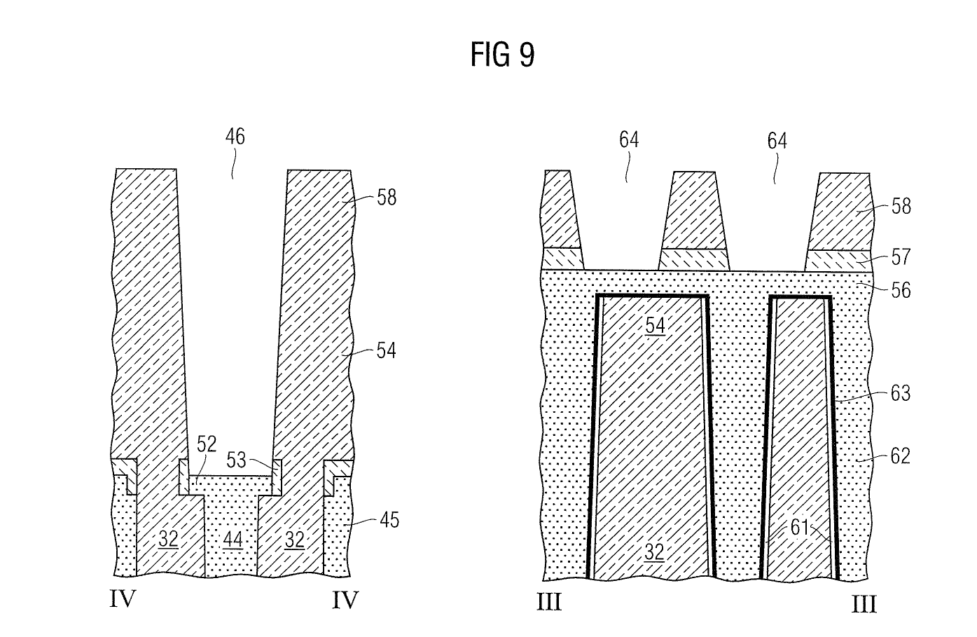

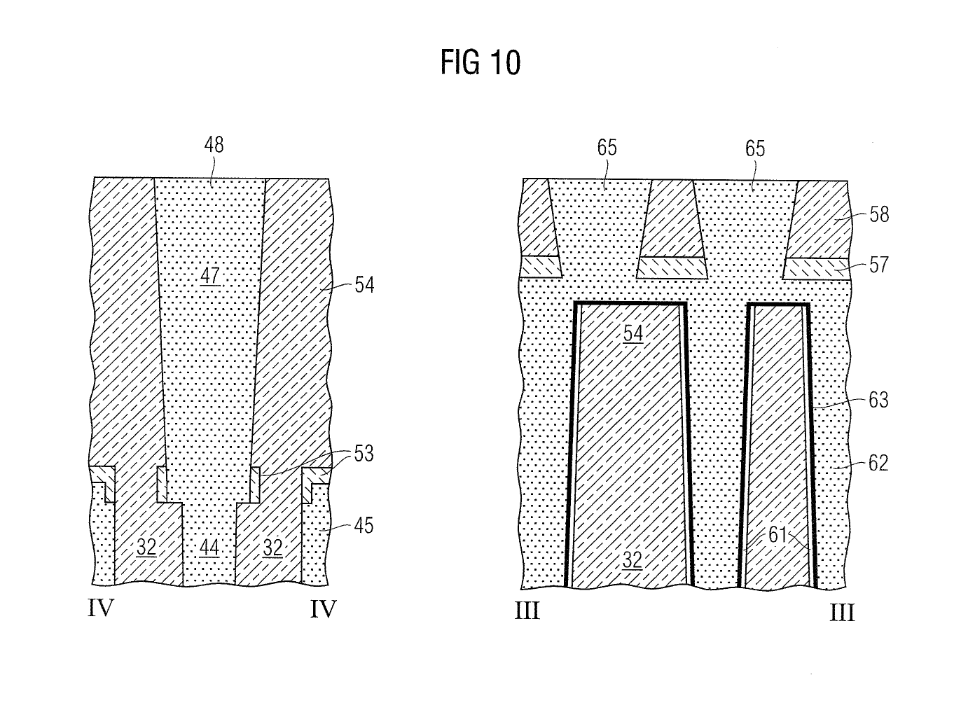

The resulting structure is shown in FIG. 9. Thereafter, the conductive material 47 is filled in each of the C1 contact openings 46 and the plate contact openings 64. For example, this may be accomplished by first depositing a liner layer, followed by a tungsten filling and a CMP step so as to obtain a planar surface. The resulting structure is shown in FIG. 10. As can be seen from FIG. 10, in the peripheral portion between IV and IV, C1 contacts 48 are formed. Each of the C1 contacts 48 is filled with the conductive filling 47. Moreover, in the array portion between III and III, plate contacts 65 for holding the second capacitor electrode 62 at a predetermined potential are formed. Also the plate contacts 65 are filled with a suitable conductive material. Thereafter, the standard processes are performed so as to complete the memory device. As a result, the memory device as is shown in FIG. 11A is obtained.

As is clearly to be understood, starting from a workpiece in which the transistors are formed in a different manner, for example, the memory device which is shown in FIG. 12 may be obtained.

FIG. 13 shows an exemplary view of a memory device, comprising a memory cell array I and a peripheral portion II. The memory cell array I comprises a plurality of memory cells 15, each of the memory cells 15 comprising a storage capacitor 6 and an access transistor 2. The storage capacitor 6 comprises a first and a second capacitor electrode 61, 62, the first capacitor electrode 61 being connected with the source/drain region 24 of the access transistor. The specific arrangement shown in FIG. 13 of the individual memory cells 15 is only by way of example and in no way limiting. As can further be seen from FIG. 13, bitlines 26 are connected via bitline contacts with the second source/drain portions 25. Moreover, wordlines 22 are connected with corresponding gate electrodes 20 of each of the transistors 2. In the shown layout, the wordlines 22 extend perpendicularly with respect to the bitlines 26. Nevertheless, as can also be gathered from FIG. 11, the wordlines 22 and the bitlines 26 can be arranged in any arbitrary manner. Nevertheless, they may intersect at a predetermined angle. In addition, the wordlines and the bitlines 26 need not necessarily be implemented as straight lines. In contrast, they may as well be implemented as angled lines.

The support portion II refers to a portion at the edge of the memory cell array in which support circuits such as decoders, sense amplifiers 14 and wordline drivers 13 for activating a wordline are located. Generally, the peripheral portion of a memory device includes circuitry for addressing memory cells and for sensing and processing the signals received from the individual memory cell.

While the memory device and method of manufacturing a memory device have been described in detail with reference to specific embodiments thereof, it will be apparent to one of ordinary skill in the art that various changes and modifications can be made therein without departing from the spirit and scope thereof. Accordingly, it is intended that the described device and method covers the modifications and variations of this memory device and method provided they come within the scope of the appended claims and their equivalents.

1. An integrated circuit comprising a memory device, the memory device comprising:
an array of memory cells, where each of the memory cells includes a storage capacitor, wherein a first capacitor electrode of the storage capacitor extends to a first height measured from a bottom portion of the first capacitor electrode to a top portion of the first capacitor electrode; and
a peripheral portion including:
peripheral circuitry to control read and write operations of the array of memory cells, the peripheral circuitry being connected to the array of memory cells; and
a wiring layer including first lines, wherein a bottom surface of each of the first lines is disposed at a second height that is greater than 0.25 times the first height, the second height being measured from the bottom portion of the first capacitor electrodes to a bottom surface of the first lines, and wherein each of the first lines has a line thickness that is measured in a direction perpendicular to the substrate surface and that is less than 200 nm.

2. The memory device of claim 1, wherein the bottom surface of each of the first lines is disposed at a second height that is greater than 0.33 times the first height.

3. The memory device of claim 2, wherein the bottom surface of each of the first lines is disposed at a second height that is greater than 0.5 times the first height.

4. The memory device of claim 3, wherein the bottom surface of each of the first lines is disposed at a height that is greater than 0.6 times the first height.

5. The memory device of claim 4, wherein the bottom surface of each of the first lines is disposed at a second height that is greater than 0.75 times the first height.

6. The memory device of claim 1, wherein the thickness of each of the first lines is less than 150 nm.

7. The memory device of claim 6, wherein the thickness of each of the first lines is less than 100 nm.

8. The memory device of claim 1, wherein no further wiring layer is provided between the wiring layer and the substrate surface.

9. The memory device of claim 1, further comprising contacts connecting selected ones of the first lines with components being disposed adjacent to the substrate surface.

10. The memory device of claim 1, wherein each memory cell of the array of memory cells comprises an access transistor comprising first and second source/drain regions formed in the substrate and a gate electrode to control an electrical current flowing between the first and the second source/drain regions, the gate electrode forming part of a conesponding word line such that an upper surface of the wordline is disposed beneath the surface of the substrate.

11. The memory device of claim 10, wherein:
the array of memory cells further comprises bitlines connected to second source/drain regions of corresponding transistors of the array of memory cells;
the peripheral portion further comprises transistors, each of the transistors of the peripheral portion comprising a source portion, a drain portion, and a gate electrode to control an electrical current flowing between the source portion and the gate electrode; and
the upper surface of the bitlines in the array of memory cells is disposed at the same height as the upper surface of the gate electrodes in the peripheral portion.

12. The memory device of claim 1, wherein:
the peripheral portion further comprises transistors, the transistors of the peripheral portion comprising a source portion, a drain portion and a gate electrode to control an electrical cunent flowing between the source and the gate electrode, and
the memory device further comprises a further conductive layer disposed on top of the source and the drain portions of the peripheral portion transistors.

13. The memory device of claim 12, wherein the first capacitor electrode of each of the storage capacitors is connected to an access transistor via a capacitor contact, and a portion of the conductive layer is disposed in the array of memory cells between a capacitor contact and the first capacitor electrode of the storage capacitors.

14. The memory device of claim 1, wherein the first capacitor electrodes are hollow body shaped and a capacitor dielectric and a second capacitor electrode material are disposed inside each of the hollow body shapes, adjacent first capacitor electrodes with hollow bodies being insulated from each other by an insulating material.

15. The memory device of claim 1, wherein the first capacitor electrodes are hollow body shaped, and a dielectric material and a second capacitor electrodes are disposed inside and outside each of the hollow body shapes.

16. An integrated circuit comprising a memory device, the memory device comprising:
an array portion including an array of memory cells, wherein each of the memory cells includes a storage component extending to a first height, the first height being measured from a bottom portion to a top portion of the storage component; and
a peripheral portion including:
peripheral circuitry to control read and write operations of the array of memory cells, the peripheral circuitry being connected to the array of memory cells via lines; and
a wiring layer provided in the peripheral portion, the wiring layer including first lines, wherein a bottom surface of each of the first lines is disposed at a second height, the second height being greater than 0.25 times the first height, the second height being measured from the bottom portion of the storage component to a bottom surface of the first lines and wherein each of the first lines has a line thickness, the line thickness being measured in a direction perpendicular to the substrate surface and less than 200 nm.

17. A method of forming an integrated circuit comprising a memory device, the method comprising:
forming a memory cell array:
forming peripheral circuitry in a peripheral region for controlling the memory cell array;
forming a first insulating layer over at least a portion of the memory cell array and the peripheral circuitry;
forming first contacts and a first wiring layer in the first insulating layer in the peripheral region such that the first wiring layer is adjacent to a surface of the first insulating layer;
forming a second insulating layer over the surface of the first insulating layer; and
forming storage capacitors in the memory cell array and providing second contacts in the peripheral region, the second contacts being in contact with the first wiring layer.

18. The method of claim 17, wherein the first wiring layer is disposed on the surface of the first insulating layer.

19. The method of claim 17, wherein the first wiring layer is disposed beneath the surface of the first insulating layer.

20. The method of claim 17, wherein each of the storage capacitors includes a first capacitor electrode, a second capacitor electrode and a capacitor dielectric disposed between the first and second capacitor electrodes, the method further comprising:
providing plate contacts that are in contact with the second capacitor electrodes, wherein the plate contacts are simultaneously formed with the second contacts.

21. An integrated circuit comprising a memory device, the memory device comprising:
an away of memory cells, where each of the memory cells includes a storage capacitor, wherein a first capacitor electrode of the storage capacitor extends to a first height measured from a bottom portion of the first capacitor electrode to a top portion of the first capacitor electrode; and
a peripheral portion including:
peripheral circuitry configured to control read and write operations of the array of memory cells, the peripheral circuitry being connected to the array of memory cells; and
a wiring layer including first lines, wherein the first lines lie between the first height and the bottom portion of the first capacitor electrode.
